(19) United States
(12) Patent Application Publication
(10) Pub. No.: US 2009/0139563 A1
(43) Pub. Date: Jun. 4, 2009

(54) SOLAR ENERGY EXPLOITING DEVICE

(76) Inventor: WEI-HUNG WUNG, Taipei City (TW)

Correspondence Address: LEONG C LEI, PMB # 1008, 1867 YGNACIO VALLEY ROAD, WALNUT CREEK, CA, 94598, US

(21) Appl. No.: 11/946,882

(22) Filed: Nov. 29, 2007

(51) Int. Cl. H01L 31/052

(52) U.S. Cl. 136/246

(57) ABSTRACT

The solar energy exploiting device contains a flat base and a transparent stand having a flat top side and two parallel walls raised perpendicularly from a top side of the base. One or more solar panels, electrically connected in series or in parallel, are attached to the top side or beneath the top side of the stand, facing downward towards the base. Two reflection mirrors are positioned besides the two walls of the stand such that each reflection mirror is slanted at an angle from the top side of the base and has its reflection surface facing towards the solar panel.

### (a) TECHNICAL FIELD OF THE INVENTION

The present invention generally relates to devices to exploit solar energy, and more particularly to such a device having a solar panel and reflection mirrors arranged in a structure.

### (b) DESCRIPTION OF THE PRIOR ART

The exploitation of solar energy has been considered a promising technology and an effective means to counter the depleted natural energy sources. Most of the existing devices to exploit solar energy require a panel of solar cells to produce electricity from the sunlight. These solar panels are usually quite expensive and the conversion efficiency still has a significant room for improvement. Even the issue of making the solar panel to receive as much sunlight as possible turns out to be not quite as simple to solve as one can imagine.

### SUMMARY OF THE INVENTION

Accordingly, a novel solar energy exploiting device is provided herein which contains a flat base and a transparent stand having a flat top side and two parallel walls raised perpendicularly from a top side of the base. One or more solar panels, electrically connected in series or in parallel, are attached to the top side or beneath the top side of the stand, facing downward towards the base. Two reflection mirrors are also positioned besides the two walls of the stand, respectively, such that each reflection mirror is slanted at an angle from the top side of the base and has its reflection surface facing towards the solar panel.

A large number of the solar energy exploiting devices can be densely aligned and arranged in an array so as to achieve a large required power.

The foregoing objectives and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a perspective view showing a solar energy exploiting device according to an embodiment of the present invention.

FIG. 2 is a profile view showing the device of FIG. 1.

FIG. 3 is a schematic diagram showing some trajectories of sun beams shone on the device of FIG. 1.

FIG. 4 is a schematic diagram showing an application scenario of the device of FIG. 1 where the device is located on a swivel arm.

FIG. 5 is a schematic diagram showing an application scenario of the device of FIG. 1 where a large number of the devices are densely arranged in an array.

FIG. 6 is a perspective view showing a solar energy exploiting device according to another embodiment of the present invention.

FIG. 7 is a profile view showing the device of FIG. 6.

### DETAILED DESCRIPTION OF THE PREFERRED EMBODIMENTS

The following descriptions are exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

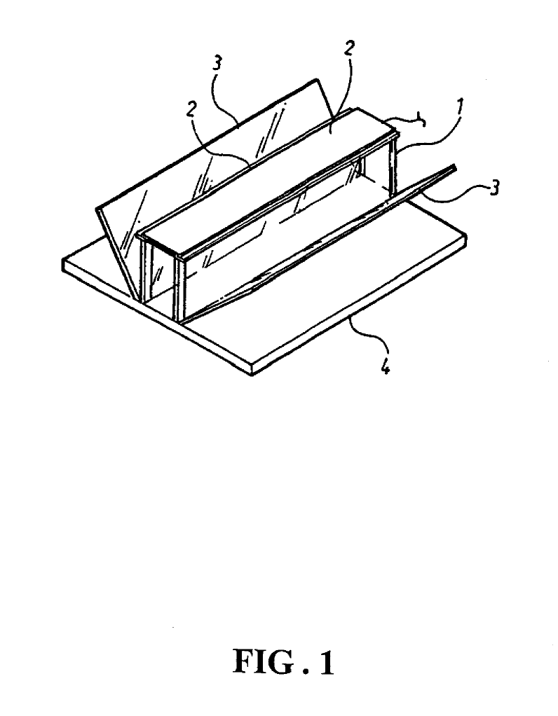

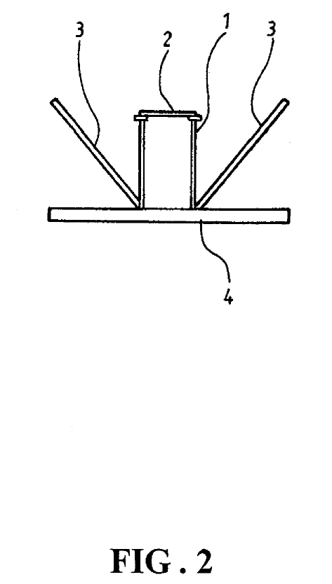

As shown in FIGS. 1 and 2, a solar energy exploiting device according to an embodiment of the present invention contains a flat base 4 and, on a top side of the flat base 4, a stand 1 having an inversed-U shaped cross section made of a transparent material is positioned and extended between two opposing sides of the base 4. One or more solar panels 2, electrically connected in series or in parallel, are attached to a top side or beneath the top side of the stand 1, facing downward towards and parallel to the top side of the base 4.

As illustrated, the stand I has two parallel walls (not numbered) raised perpendicularly from the top side of the base 4. Two flat reflection mirrors 3 are also positioned on the top side of the base 4 besides the two walls of the stand 1, respectively, such that each reflection mirror 3 has one of its sides coincides with a bottom edge of the walls. Furthermore, each reflection mirror 3 is slanted at an angle (between 0 and 90 degrees) from the top side of the base 4 and has its reflection surface facing towards the solar panel 2.

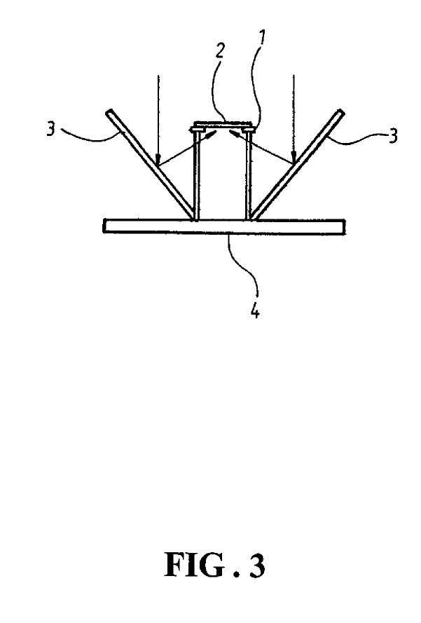

As shown in FIG. 3, due to the configuration of the reflection mirrors 3, no matter where the sun or light source is located, a significant portion, if not all, of the sun light is reflected and projected on the solar panel 2 for conversion into electricity. The utilization of the solar panel 2 therefore is more fully exploited, achieving a high conversion efficiency.

A number of experiments have been conducted to compare the performance of a device of FIGS. 1 to 3, and a similar device but without the reflection mirror 3.

Under a fluorescent lamp and if the solar panels 2 are parallel-connected, the device with no mirror produces: 1.65V, 0.794 mA, Power=0.0013 while the present invention produces: 2.11V, 1.086 mA, Power=0.0023 (about 1.75 times of the device with no mirror).

Under a fluorescent lamp and if the solar panels 2 are series-connected, the device with no mirror produces: 6.47V, 0.251 mA, Power=0.0016 while the present invention produces: 6.91 V, 0.348 mA, Power=0.0024 (about 1.48 times of the device with no mirror).

Under a solar lamp and if the solar panels 2 are parallel-connected, the device with no mirror produces: 3.32V, 14.7 mA, Power=0.049 while the present invention produces: 3.58V, 30.3 mA, Power=0.108 (about 2.22 times of the device with no mirror).

Under a solar lamp and if the solar panels 2 are series-connected, the device with no mirror produces: 10.73V, 5.13 mA, Power=0.055 while the present invention produces: 11.36V, 8.51 mA, Power=0.097 (about 1.75 times of the device with no mirror).

As the above data indicates, the present invention indeed provides significantly superior performances. On the other hand, for the same power requirement, the present invention can be applied with smaller solar panels and therefore enjoys a much lower cost.

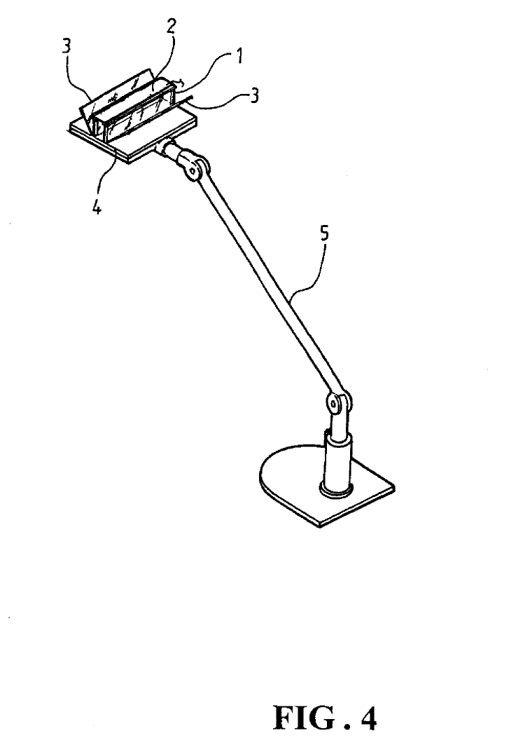

As shown in FIG. 4, the solar energy exploiting device can be placed on a swivel arm 5 which can be adjusted in accordance with the location of the sun or light source so that the device can receive the greatest amount of light.

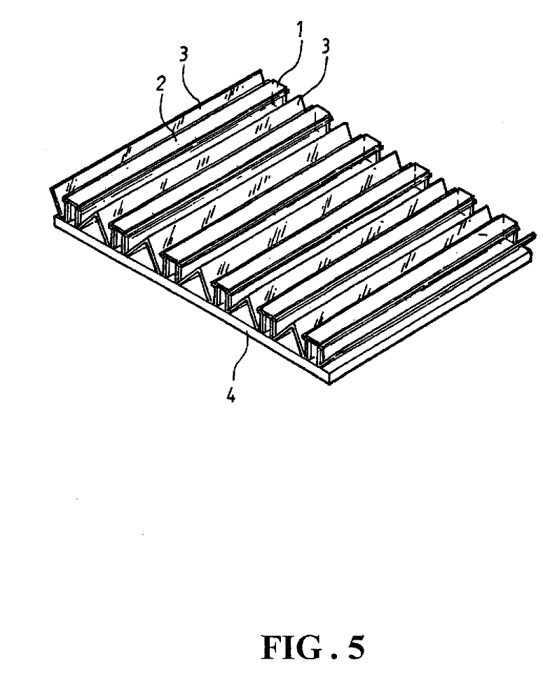

As shown in FIG. 5, when a greater power is required, a large number of the solar energy exploiting devices can be arranged densely in an array on the top side of the base 4.

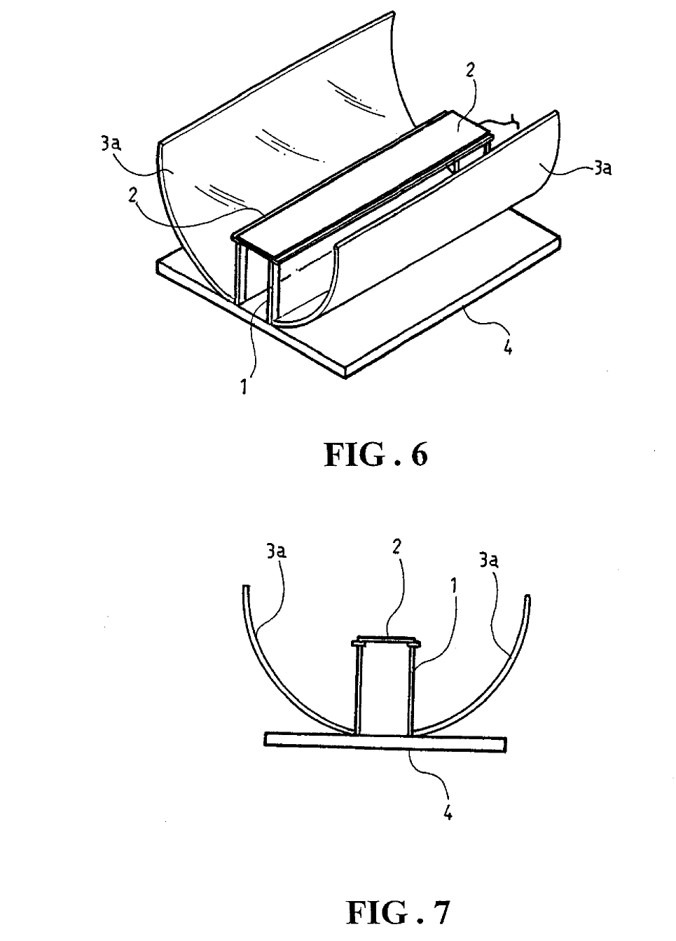

As shown in FIGS. 6 and 7, instead of using flat mirrors 3, mirrors 3a having a curved surface that arcs away from the stand 1 can also be used. The curved mirrors 3a provides an even better collimating effect to the light beams towards the solar panel 2.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

I claim:

1. A solar energy exploiting device, comprising:
a flat base; and
an energy conversion member having
a transparent stand having a flat top side on top of two parallel walls raised perpendicularly on a top side of said base;
at least a solar panel facing downward towards said top side of said base, said solar panel attached to or beneath said top side of said stand; and
two reflection mirrors besides said two walls, respectively, each reflection mirror having one of a flat reflection surface and a curved reflection surface, each reflection mirror slanted for an angle from said top side of said base with said reflection surface facing towards said solar panel.

2. The solar energy exploiting device according to claim 1, wherein said stand has an inversed-U shaped cross section.

3. The solar energy exploiting device according to claim 1, wherein, if there are a plurality of said solar panels, said solar panels are configured in one of a series-connection and a parallel connection.

4. The solar energy exploiting device according to claim 1, further comprising at least one additional energy conversion member wherein all energy conversion members are arranged into an array on said top side of said base.
